(19) United States
(12) Patent Application Publication
(10) Pub. No.: US 2007/0138916 A1
(43) Pub. Date: Jun. 21, 2007

(54) Piezoelectric device

(75) Inventor: Yugo Koyama, Ina-shi (JP)

Correspondence Address: OLIFF & BERRIDGE, PLC, P.O. BOX 19928, ALEXANDRIA, VA, 22320, US

(73) Assignee: EPSON TOYOCOM CORPORATION, TOKYO (JP)

(21) Appl. No.: 11/638,358

(22) Filed: Dec. 14, 2006

(30) Foreign Application Priority Data
Dec. 21, 2005 (JP) 2005-367527

(51) Int. Cl. H01L 41/053

(52) U.S. Cl. 310/348

(57) ABSTRACT

A piezoelectric device includes a piezoelectric resonator and an electronic element mounted horizontally on an upper surface of a substrate, and the electronic element being lower in height than the piezoelectric resonator. The entire upper surface side of the substrate is covered with resin in a manner that the upper surface of the piezoelectric resonator is exposed outside.

### BACKGROUND

1. Technical Field

The present invention relates to a piezoelectric device equipped with a piezoelectric resonator and an electronic element on a substrate.

2. Related Art

Piezoelectric devices are widely used in small-sized information equipment such as hard disc drives (HDDs), mobile computers, and IC cards and in mobile communication equipment such as cellular phones, car phones, and paging systems.

FIG. 9 is a schematic perspective of a conventional piezoelectric device 1 (refer to JP-UM-A-1-82507 on microfilm). In the drawing, the piezoelectric device 1 includes a piezoelectric resonator 3 and a semiconductor chip 4 mounted on the upper surface of a substrate 2.

More specifically, conductive patterns (not shown) are formed on the upper surface of the substrate 2; the piezoelectric resonator 3 is mounted on the conductive patterns by soldering; and the semiconductor chip 4 is mounted next to this piezoelectric resonator 3. This structure enables the piezoelectric device 1 to be thinned.

Then, after the semiconductor chip 4 and the conductive patterns are electrically coupled by bonding wires 5, the semiconductor chip 4 and the bonding wires 5 are coated with resin 6.

However, with this piezoelectric device 1, even though the semiconductor chip 4 and the bonding wire 5 are protected by the resin 6, the portion where the piezoelectric resonator 3 is mounted on the substrate 2 by soldering is not coated with resin 6 and thus not sufficiently protected.

In contrast, in FIG. 10 illustrating a schematic cross section of a conventional piezoelectric device 7, the entire upper side of the substrate 2 is molded with the resin 6. Therefore, with this piezoelectric device 7, every element on the substrate 2 is protected (refer to JP-A-7-162236).

However, in recent years, electronic equipment such as the information equipment becomes increasingly thinner, and such thinner piezoelectric devices are demanded as used in such electronic equipment. Although the piezoelectric device 7 shown in FIG. 10 is certainly capable of protecting every element on the substrate 2, it is not capable of meeting such demand because it becomes large in height as the resin 6 is heaped on the entire device 7.

### SUMMARY

An advantage of the invention is to provide a piezoelectric device that can protect each element and can be made low in height.

According to an aspect of the invention, a piezoelectric device having a substrate, a piezoelectric resonator mounted on an upper surface of the substrate and an electronic element mounted horizontally on the upper surface of the substrate, the electronic element being lower in height than the piezoelectric resonator, is such that: the entire upper surface side of the substrate is covered with resin in a manner that the upper surface of the piezoelectric resonator is exposed outside.

With this structure, because the piezoelectric resonator and the electronic element are mounted horizontally on the upper surface of the substrate, this piezoelectric device may be made thinner than a piezoelectric device whose piezoelectric resonator and electronic element are arranged on top of the other in the height direction.

Further, since the entire upper surface side of the substrate is covered with resin, each of the elements such as the piezoelectric resonator and electronic element on the substrate may be sealed with resin and protected.

Furthermore, this resin is disposed in such a manner that the upper surface of the piezoelectric resonator is exposed outside. Because there is no resin above the upper surface of the piezoelectric resonator and the electronic element is lower in height than the piezoelectric resonator, the resin over the electronic element does not become higher than the upper surface of the piezoelectric resonator.

Consequently, according to the aspect of the invention, it is possible to provide the piezoelectric device that can protect each element and can be made low in height.

It is preferable that a plurality of terminals and wiring patterns that electrically couple these terminals be formed on the upper surface of the substrate, and that the wiring patterns be covered with an insulating layer in a manner that the plurality of terminals are exposed.

With this structure, because the wiring patterns that electrically couple the plurality of terminals on the surface of the substrate are covered with the insulating layer, it is possible to prevent a problem like short circuit that may occur when, for example, the solder used to couple the piezoelectric resonator with the upper surface of the substrate attaches to the wiring patterns. Further, because the terminals are not covered with the insulating layer and exposed, an element such as the piezoelectric resonator may be coupled to these terminals.

It is also preferable that the piezoelectric resonator be arranged off the center of the substrate in a plan view.

According to this structure, the piezoelectric resonator is arranged off the center of the substrate in the plan view. Also, as has been stated above, the surface of the piezoelectric resonator is exposed outside. Therefore, even when seen from above, the orientation of the piezoelectric device may be confirmed by judging from the position of the upper surface of the piezoelectric resonator exposed outside.

It is preferable that the upper surface exposed outside the piezoelectric resonator be an upper surface of a transparent lid that seals inner space of a package housing a piezoelectric resonator element.

According to this structure, the upper surface exposed outside the piezoelectric resonator is the upper surface of the transparent lid that seals the inner space of the package housing the piezoelectric resonator element. Therefore, even after the upper side of the substrate is sealed with resin, frequencies may be adjusted by irradiating a laser beam through the transparent lid on the piezoelectric resonator element housed in the package of the piezoelectric resonator.

It is further preferable that the resin covering the upper surface of the electronic element be lower in height than the upper surface of the piezoelectric resonator.

With this structure, the resin covering the upper surface of the electronic element is lower than the upper surface of the piezoelectric resonator. Therefore, there is space above the electronic element that can be used efficiently.

### BRIEF DESCRIPTION OF THE DRAWINGS

The invention will be described with reference to the accompanying drawings, wherein like numbers reference like elements.

FIG. 1 is a schematic plan view of a piezoelectric oscillator exemplifying a piezoelectric device of an embodiment of the invention.

FIG. 2 is a schematic cross-sectional diagram taken on a line A-A of FIG. 1.

FIG. 3 is a schematic plan diagram only of a substrate of FIG. 1.

FIG. 4 is a flowchart corresponding to a working example of a method for manufacturing the piezoelectric oscillator of the embodiment of the invention.

FIGS. 5A through 5C are conceptual diagrams corresponding to processes ST1 through ST3 of FIG. 4.

FIGS. 6D through 6F are conceptual diagrams corresponding to processes ST4 through ST7 of FIG. 4.

FIG. 7 is a conceptual diagram corresponding to a process ST8 of FIG. 4.

FIG. 8 is a schematic cross-sectional diagram of the piezoelectric oscillator of a modified working example of the embodiment of the invention.

FIG. 9 is a schematic perspective diagram of a conventional piezoelectric device.

FIG. 10 is a schematic cross-sectional diagram of a conventional piezoelectric device.

### DESCRIPTION OF EXEMPLARY EMBODIMENT

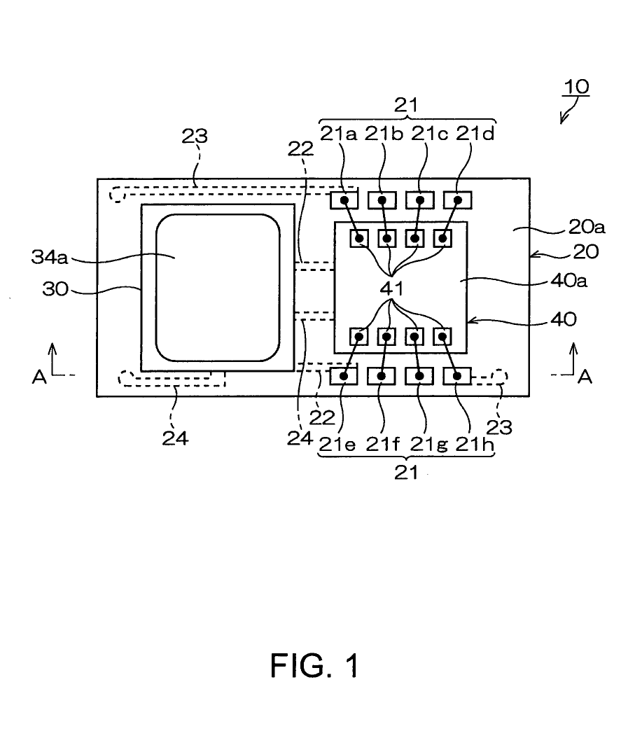

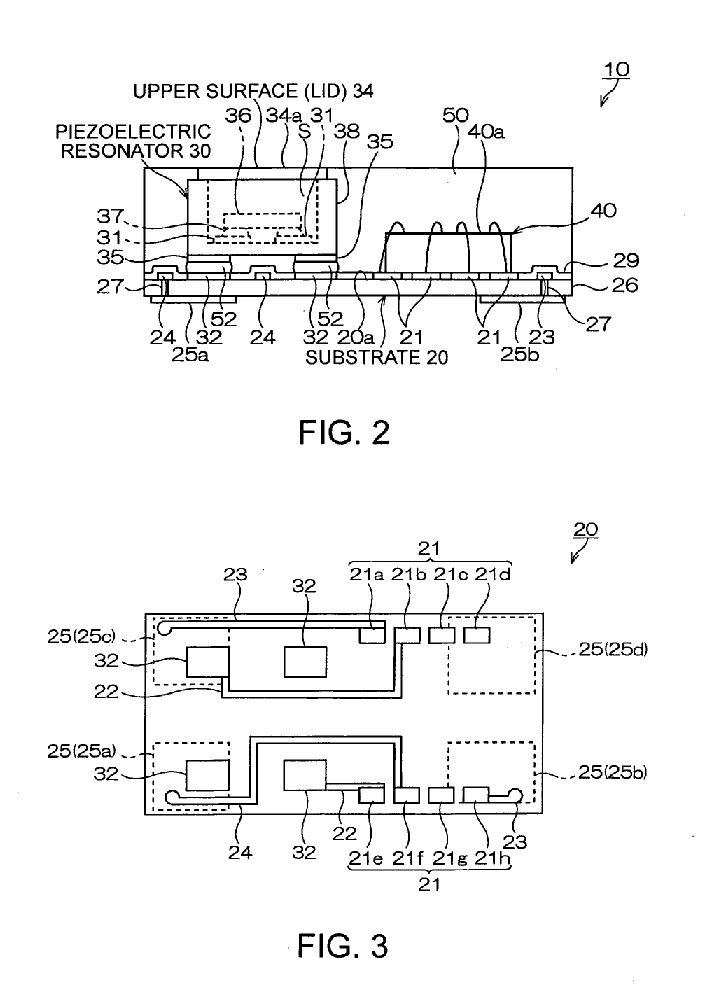

FIGS. 1, 2, and 3 show a piezoelectric oscillator 10 exemplifying the piezoelectric device of the embodiment of the invention. FIG. 1 is a schematic plan view of the piezoelectric oscillator 10; FIG. 2 is a schematic cross-sectional diagram taken on a line A-A of FIG. 1; and FIG. 3 is a schematic plan diagram only of a substrate of FIG. 1. For convenience sake, FIG. 1 is shown through resin 50 which will be described hereafter. Also, for convenience sake, FIG. 3 is shown through an insulating layer formed on the substrate as will be described hereafter.

In these drawings, the piezoelectric oscillator 10 includes a piezoelectric resonator 30 and an electronic element 40 mounted horizontally on an upper surface 20a of a substrate 20.

As shown in FIG. 2, the piezoelectric resonator 30 is a surface-mounting resonator having a rectangular package 38 with inner space S formed therein. There are disposed electrodes 31 made of, e.g., nickel plate and gold plate on the tungsten-metallized inside bottom surface exposed in the inner space S of this package 38. These electrodes 31 are electrically coupled to part of outside terminals 35 disposed at four corners of the outer bottom of the package 38. Also, a piezoelectric resonator element 36 made of a piezoelectric material such as quartz crystal is bonded and fixed to the upper surface of the electrodes 31 using a conductive adhesive 37.

Further, a lid 34 is bonded on an open end-surface of the package 38 using a brazing material (not shown), thereby sealing the inner space S.

The lid 34 may certainly be made of metal; however, in the embodiment, the lid 34 is composed of a light-transmitting material, a glass sheet, in particular, so that a metal-covered portion (not shown) of the piezoelectric resonator element 36 is irradiated with a laser beam from outside in order to adjust the frequencies by a mass reduction system. A suitable material to form a transparent lid 34 is generally glass, and such a glass material is, for example, borosilicate glass which is produced into a glass sheet by, for example, a down-draw method.

The electronic element 40 is an oscillation circuit element (hereinafter referred to as an “IC chip”) composed of a semiconductor element and the like having at least a circuit structure to oscillate the piezoelectric resonator 30. As shown in FIG. 1, there is a plurality of electrode pads 41 on an upper surface 40a of the electronic element 40. Depending on the type of the IC chip, there may certainly be more or fewer number and types of the electrode pads 41 of the IC chip 40 than what is shown in FIG. 1; however, in the embodiment, the IC chip 40 includes, e.g., gate/drain (G/D) terminals electrically coupled to the piezoelectric resonator 30, input/output terminals of the oscillation circuit coupled to mounting terminals, control terminals for writing data in the oscillation circuit, and a ground terminal.

In order to thinly form the piezoelectric device, the IC chip 40 is not arranged vertically to the piezoelectric resonator 30 but is mounted horizontally to the piezoelectric resonator 30 on the upper surface 20a of the substrate 20. Also, the IC chip 40 is formed slightly smaller than the piezoelectric resonator 30 in the horizontal direction and taller than the piezoelectric resonator 30 in the height direction, and it is bonded to the substrate 20 using an adhesive (not shown).

Further, the IC chip 40 is electrically coupled to terminals 21 on the substrate 20 by wire bonding. Although the IC chip 40 of the embodiment is thus bonded to the substrate 20 by the adhesive and electrically coupled to the terminals 21 by wire bonding, it may certainly be electrically and mechanically bonded to the terminals of the substrate 20 by what is known as flip-chip bonding.

The substrate 20 is a member to which the piezoelectric resonator 30 and the IC chip 40 are electrically and mechanically connected, and it may be a rigid substrate or a flexible substrate.

In the embodiment, the substrate 20 is formed so thinly that it has flexibility. More specifically, the substrate 20 includes: an insulating film 26 composed of a material such as polyimide or glass epoxy so as to be, e.g., thermally resistant, and a plurality of conductive patterns 21 through 24 and 32 formed on the upper surface of this insulating film 26. The conductive patterns 21 through 24 and 32 are composed of a conductive material such as copper foil and formed on the upper surface 20a of the substrate 20 by such techniques as etching, printing, vapor deposition, and plating.

In the embodiment, as shown in FIGS. 1 and 3, the conductive patterns 21 through 24 and 32 are composed of: the plurality of terminals 21 and 32 that become pads to electrically or electrically and mechanically couple the piezoelectric resonator 30 to the IC chip 40, and wiring patterns 22 through 24 to electrically couple these plurality of terminals 21 and 32 to each other and/or to electrically couple the terminals 21 with the mounting terminals 25.

The terminals 32 are piezoelectric resonator electrodes to electrically and mechanically couple the piezoelectric resonator 30 to the substrate 20, and they are arranged opposite from the outside terminals 35 formed at the four bottom corners of the piezoelectric resonator 30 and bonded to the outside terminals 35 by solders 52.

Further, the terminals 21 are IC chip electrodes for the electrical connection of the IC chip 40 and are wire-bonded to the electrode pads 41 of the IC chip 40.

More specifically, as shown in FIGS. 1 and 3, terminals 21a, 21h are electrically coupled to mounting terminals 25b, 25c through the wiring patterns 23, 23 and of conductive members inside via holes 27, 27 (see FIG. 2) formed at the end portions of these wiring patterns 23, 23 and become the input/output terminals of the oscillation circuit. Also, terminals 21b, 21e are electrically coupled, through the wiring patterns 22, 22, to the terminals 32, 32 bonded to the piezoelectric resonator 30 and become the gate/drain terminals. Further, terminals 21c, 21d, and 21g become the terminals for writing date in the IC chip 40. Furthermore, a terminal 21f is electrically coupled to a mounting terminal 25a through the wiring pattern 24 and the conductive member inside the via hole 27 (see FIG. 2) formed at the end portion of this wiring pattern 24 and becomes the ground terminal.

It should be noted that, since the substrate 20 is formed so thinly that it has flexibility, it is preferable that the substrate 20 be not bent when bonding the piezoelectric resonator 30 or the IC chip 40 to the substrate 20. Accordingly, the wiring patterns 22 through 24 preferably have a wide possible width so as to increase the strength of the substrate 20 a these wiring patterns are lead to a region on the upper surface 20a of the substrate 20 to which the piezoelectric resonator 30 and the IC chip 40 are bonded.

Further, as shown in FIG. 2, an insulating layer 29 covers the wiring patterns 22 through 24 while exposing the plurality of terminals 21, 32. In the embodiment, the insulating layer 29 is made of resist film, which can be made thin and can increase positional precision using a photolithography technique. Thus, the insulating layer 29 covers the entire upper surface 20a of the substrate 20, exposing only the terminals 21, 32. Additionally, the resist may be either a negative type or a positive type.

As a consequence, when bonding the piezoelectric resonator 30 and the IC chip 40 to the substrate 20, it becomes possible to effectively prevent, e.g., short circuit caused by the solders 52 between the wiring patterns 22 and the wiring patterns 24 located under the piezoelectric resonator 30 or between the terminals 32 and the wiring pattern 24.

As for the piezoelectric device 10, as shown in FIG. 2, the fixed resin 50 entirely covers the upper surface 20a of the substrate 20 in a manner that an upper surface 34a of the piezoelectric resonator 30 is exposed outside.

That is, the resin 50 covers the upper side of the substrate 20, including the bonded portion between the piezoelectric resonator 30 and the terminals 32 and the wire-bonded portion between the IC chip 40 and the terminals 21 so as to protect each of these elements. Further, since the substrate 20 is made so thin as to have flexibility as has been described, when the whole substrate 20 is fixed with the resin 50, the strength of the piezoelectric device 10 is secured as a whole.

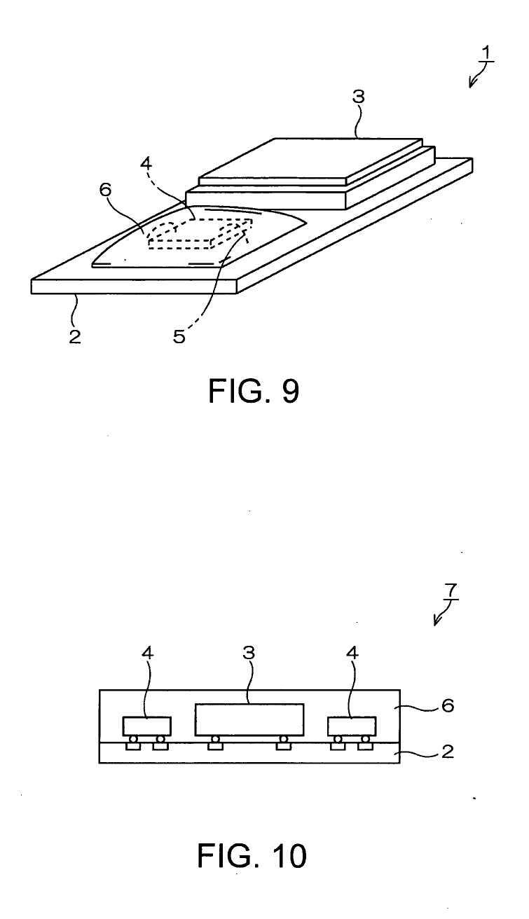

In addition, the resin 50 is formed in a manner that it seals the upper side of the substrate 20 while exposing the upper surface 34a of the piezoelectric resonator 30 (in the embodiment, the upper surface of the lid 34), and that the position in the height direction of the upper surface of the piezoelectric resonator 30 matches with the position in height of the upper surface of the resin 50. Consequently, the piezoelectric oscillator 10 can have the same height as that of the conventional piezoelectric device whose portion of the piezoelectric resonator 30 is unsealed with resin (see FIG. 9). Additionally, for the resin 50, a thermo-curing liquid resin may be used.

Also, the piezoelectric resonator 30 whose upper surface 34a (in the embodiment, the upper surface of the lid 34) is exposed outside is located off the center of the substrate 20 in the plan view. Consequently, although the orientation of the piezoelectric oscillator 10 is conventionally confirmed by, e.g., cutting off a portion of the mounting terminals, there is no need to do so anymore because, even when seen from above, the orientation of the piezoelectric oscillator 10 can be confirmed by judging from the position of the upper surface 34a of the piezoelectric resonator 10 exposed outside the piezoelectric resonator 30.

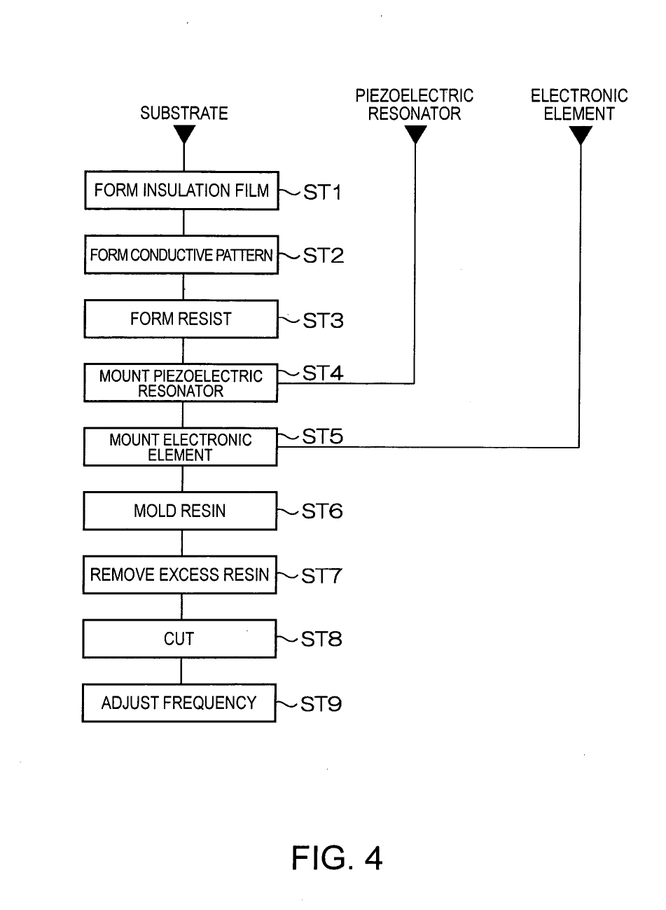

Next, a working example of a method for manufacturing the piezoelectric oscillator 10 will be described with reference to FIGS. 4 through 7.

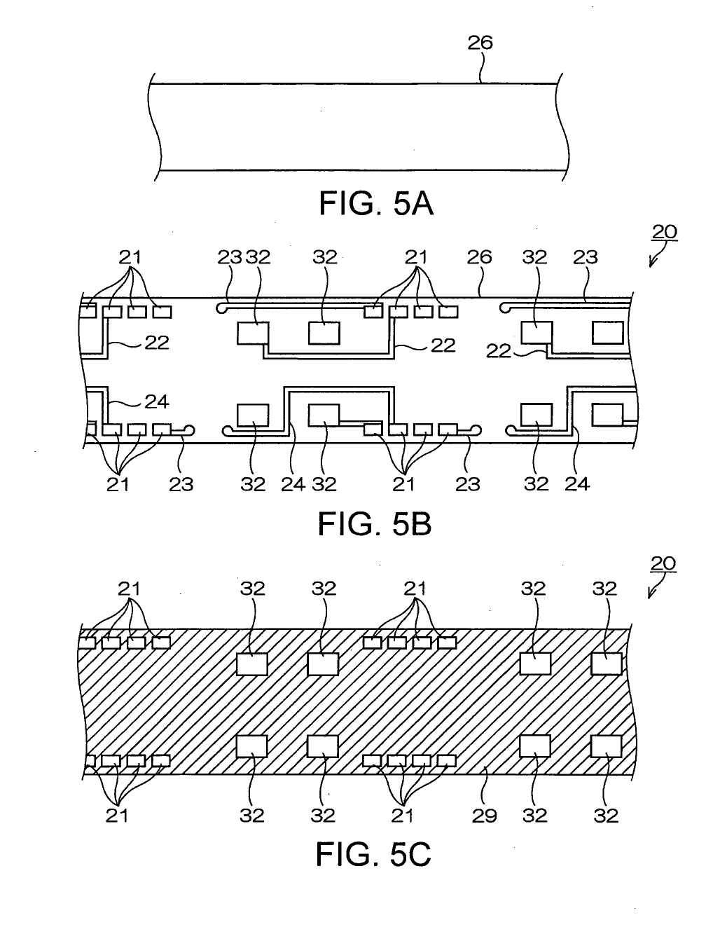

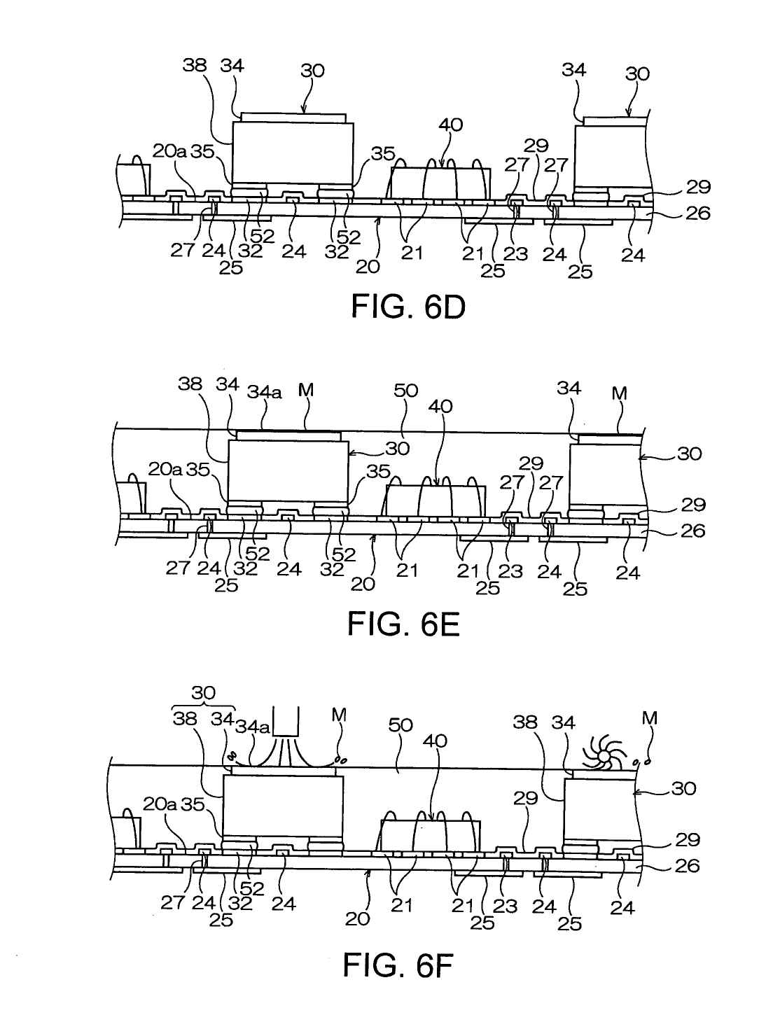

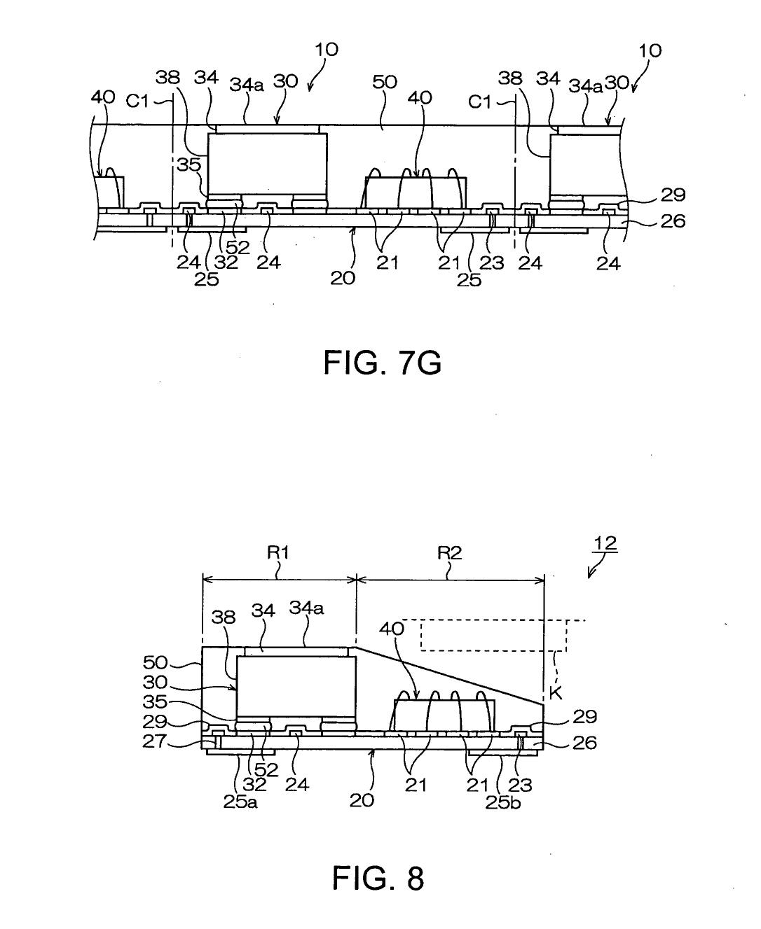

FIG. 4 is a flowchart corresponding to the working example of the method for manufacturing the piezoelectric oscillator 10. FIGS. 5A through 5C are conceptual diagrams corresponding to processes ST1 through ST3 of FIG. 4. FIGS. 6D through 6F are conceptual diagrams corresponding to processes ST4 through ST7 of FIG. 4. FIG. 7 is a conceptual diagram corresponding to a process ST8 of FIG. 4.

As shown in FIG. 4, with the piezoelectric oscillator 10, the substrate, the piezoelectric resonator, and the IC chip (the electronic element) are prepared separately and connected to each other.

In the case of the substrate, as shown in FIG. 5A, in order to form a plurality of piezoelectric oscillators, the insulating film 26 composed of polyimide or the like in the form of film is formed in the length corresponding to the size of the plurality of piezoelectric oscillators (ST1 of FIG. 4).

Thereafter, as shown in FIG. 5B, the conductive patterns 21 through 24 and 32 are disposed by such techniques as etching, printing, vapor deposition, and plating, using a conductive material such as copper foil on the upper surface of the insulating film 26, thereby forming the substrate 20 (ST2 of FIG. 4).

Then, the resist is applied to the entire upper surface of the substrate 20, and the regions of the terminals 21, 32 are exposed to light through a mask. As a result, as shown in FIG. 5C, the insulating layer 29 exposing only the terminals 21, 32 is formed on the upper surface of the substrate 20, covering the wiring patterns 22, 24 disposed on the insulating film 26 (ST3 of FIG. 4).

Thereafter, as shown in FIG. 6D, the terminals 32 disposed on the upper surface 20a of the substrate 20 and the outside terminals 35 of the piezoelectric resonator 30 are coupled by the solders 52 so as to mount the piezoelectric resonator 30 on the substrate 20. Then, after bonding the IC chip 40 to the piezoelectric resonator 30 horizontally using the adhesive (not shown), the IC chip 40 and the terminals 21 are bonded by wire bonding (ST4 and ST5 of FIG. 4).

Thereafter, as shown in FIG. 6E, the entire upper side of the substrate 20 is covered with the resin 50 (ST6 of FIG. 4). The resin 50 may be formed by injecting an insulation member such as epoxy resin using a mold or may be applied by screen printing. In this case, the resin 50 is filled or applied in a manner that the upper surface 34a of the piezoelectric resonator 30 (in the embodiment, the upper surface of the lid 34) is exposed outside.

However, as shown in FIG. 6E, there are cases in which resin M may attach to the upper surface 34a of the piezoelectric resonator 30. Thus, as shown in FIG. 6F, the resin M attached to the upper surface 34a of the piezoelectric resonator 30 (in the embodiment, the upper surface of the lid 34) is removed by blasting or brushing (ST7 of FIG. 4).

Then, as shown in FIG. 7G, after dicing at positions of cut lines C1, C1 (ST8 of FIG. 4), each separated piezoelectric oscillator 10 is inspected for its oscillation characteristics (ST9 of FIG. 4). If prescribed oscillation characteristics are not exhibited and if the lid is made of glass, the frequencies are adjusted by the mass reduction system by irradiating the metal-coated portion of the piezoelectric oscillation element inside the package 38 with a laser beam through the transparent lid, since the resin 50 is not attached to the upper surface 34a of the piezoelectric resonator 30 (the upper surface of the lid 34) as shown in FIG. 7G. Further, when it is necessary to correct the frequency characteristics of the crystal resonator by the temperature, a frequency-adjusting write terminal (not shown) lead from the IC chip is provided separately on the rear surface of the substrate, and the frequencies are adjusted using this write terminal.

Because the embodiment of the invention is structured as described above, and because the piezoelectric resonator 30 and the IC chip 40 are mounted horizontally on the upper surface 20a of the substrate 20, the piezoelectric device can be made thinner than the piezoelectric device whose piezoelectric resonator 30 and IC chip 40 are arranged on top of the other in the height direction. Further, since the entire upper surface side of the substrate 20 is covered with the resin 50, each of the elements such as the piezoelectric resonator 30 and IC chip 40 on the substrate can be protected by the resin 50. Moreover, because the upper surface of the piezoelectric resonator 30 is exposed outside and there is no resin 50 on the piezoelectric resonator 30, the piezoelectric oscillator 10 can have the same height as that of the piezoelectric device whose piezoelectric resonator 30 is not coated with resin and, therefore, can be made low in height.

FIG. 8 is a schematic cross section of a piezoelectric oscillator 12 of a modified working example of the embodiment of the invention. This drawing is a schematic cross section taken on the line A-A of FIG. 1.

In this drawing, parts allotted with the same reference numbers have the same structures as those in the above-described piezoelectric oscillator 10. Thus, their descriptions will not be repeated, and mainly their differences will be described hereafter.

The difference between this piezoelectric oscillator 12 and the above-described piezoelectric oscillator 10 is the shape of the resin 50.

That is, with the piezoelectric oscillator 12, the resin 50 covering the upper surface of the IC chip 40 is lower in height than the upper surface 34a of the piezoelectric resonator 30.

More specifically, the height of the upper surface of the resin 50 in a region R1 where the piezoelectric resonator 30 is bonded is substantially equal to the substrate 20, and, in a region R2 where the IC chip 40 is bonded, the height decreases gradually from the center to the edge against the substrate 20.

The piezoelectric oscillator 12 of the modified working example of the embodiment of the invention is structured as just described, and, thus, the resin 50 covering the upper surface of the IC chip 40 is lower in height than the upper surface of the piezoelectric resonator 30. Accordingly, when such a piezoelectric oscillator 12 is mounted on electronic equipment, space is created above the IC chip 40 that can be efficiently used for disposing, for example, other electronic element K such as a battery.

The invention is not limited to the embodiment as described hereinbefore. The structures of the embodiment and working examples may be suitably omitted or combined with each other or with other structures not illustrated in the drawings.

The entire disclosure of Japanese Patent Application No. 2005-367527, filed Dec. 21, 2005 is expressly incorporated by reference herein.

What is claimed is:

1. A piezoelectric device comprising:
a substrate;
a piezoelectric resonator mounted on an upper surface of the substrate; and
an electronic element mounted on the upper surface of the substrate, the electronic element being lower in height than the piezoelectric resonator, wherein:
the entire upper surface side of the substrate is covered with resin in a manner that the upper surface of the piezoelectric resonator is exposed outside.

2. The piezoelectric device according to claim 1, further comprising:
a plurality of terminals formed on the upper surface of the substrate;
a wiring pattern formed on the upper surface of the substrate and electrically couples the plurality of terminals; the wiring pattern that is covered with an insulating layer in a manner that the plurality of terminals are exposed.

3. The piezoelectric device according to claim 1, wherein the piezoelectric resonator is arranged off the center of the substrate in a plan view.

4. The piezoelectric device according to claim 1, wherein the upper surface exposed outside the piezoelectric resonator is an upper surface of a transparent lid that seals inner space of a package housing a piezoelectric resonator element.

5. The piezoelectric device according to claim 1, wherein the resin covering the upper surface of the electronic element is lower in height than the upper surface of the piezoelectric resonator.
